(19) United States
(12) Patent Application Publication
(10) Pub. No.: US 2025/0385063 A1
(43) Pub. Date: Dec. 18, 2025

(54) A METHOD AND ARRANGEMENT FOR NEGATIVE ION PRODUCTION

(71) Applicant: Jyväskylän yliopisto, Jyväskylän yliopisto (FI)

(72) Inventors: Mikko LAITINEN, Jyväskylä (FI); Taneli KALVAS, Jyväskylä (FI); Ville TOIVANEN, Jyväskylä (FI); Jaakko JULIN, Jyväskylä (FI); Mikael REPONEN, Jyväskylä (FI); Risto KRONHOLM, Jyväskylä (FI); Akbar HOSSAIN, Jyväskylä (FI); Olli TARVAINEN, Jyväskylä (FI)

(21) Appl. No.: 18/880,043

(22) PCT Filed: Jun. 26, 2023
(86) PCT No.: PCT/FI2023/050384

§ 371 Date: Dec. 30, 2024

(30) Foreign Application Priority Data
Jun. 30, 2022 (FI) 20225597

(51) Int. Cl. H01J 27/02; H01J 27/22; H01J 27/24

(52) U.S. Cl. CPC H01J 27/028; H01J 27/22; H01J 27/24

(57) ABSTRACT

An inventive arrangement is made to produce for negative ions. It comprises a chamber with a sputtering gas, a cathode, an alkali metal in order to decrease a work function of the cathode, and an extraction channel. Further the arrangement comprises a voltage source for providing an electric field in the chamber, which electric field's lowest voltage level is on the cathode, and a light source to provide light onto the cathode.

### FIELD OF TECHNOLOGY

The invention relates to negative ion production. The negative ions are used in research work and scientific applications.

### PRIOR ART

Negative ion beams are used in accelerator-based research ranging from high energy particle physics to neutral beam heating of thermonuclear fusion reactors. In addition to international flagship projects such as LHC luminosity upgrade and ITER, negative ion beams are used in hundreds of accelerator laboratories across the world for Accelerator Mass Spectrometry (AMS) and Ion Beam Analysis (IBA) e.g. for radiocarbon dating and elemental analysis of thin films, respectively.

Negative ion beams for IBA and AMS are produced for example with Caesium Sputter lon Sources (SNICS), which are versatile devices capable of producing negative ions from a range of materials but often suffer from low intensities of certain negative ion beams, poor temporal stability of the beam current and short lifetime of the ion source components.

There are also other ways to produce negative ions, such as formation of negative ions in a gaseous plasma. Further, it has been suggested that a laser beam may have affect to the production of the negative ions.

### SHORT DESCRIPTION

The object of the invention is to provide an alternative way to produces the negative ions and also to alleviate or even eliminate the problems said above. The object is achieved in a way described in the independent claims. Dependent claims illustrate different embodiments of the invention.

A method for negative ion production according to the invention comprises step of
providing a chamber with a sputtering gas, a cathode, an alkali metal in order to decrease a work function of the cathode, and an extraction channel,
providing an electric field in the chamber, which electric field's lowest voltage level is on the cathode,
providing light onto the cathode,
as response to said provided light, inducing photo-surface interaction from the cathode, which results ionization of the sputtering gas,
bombarding the cathode by positive ions of the sputtering gas, the positive ions being directed to the cathode by the electric field, and
providing negative ions from the cathode as response to said bombarding.

An arrangement to produce for negative ions according to the invention comprises
a chamber with a sputtering gas, a cathode, an alkali metal in order to decrease a work function of the cathode, and an extraction channel,
a voltage source for providing an electric field in the chamber, which electric field's lowest voltage level is on the cathode, and
a light source to provide light onto the cathode.

In which chamber the cathode is arranged as response to said light to induce photo-surface interaction from it, which results ionization of the sputtering gas. Positive ions of the sputtering gas are arranged to bombard the cathode, which positive ions are directed to the cathode by the electric field. As response said bombarding the cathode is arranged to provide negative ions from the cathode.

### LIST OF FIGURES

In the following, the invention is described in more detail by reference to the enclosed drawings, where

FIG. 1 illustrates an example of an inventive arrangement according to the invention,

FIG. 2 illustrates an example of a cathode surface of the invention releasing photoelectrons,

FIG. 3 illustrates, an example of a cation bombarding of the cathode of FIG. 3,

FIG. 4 illustrates another example of the inventive arrangement according to the invention,

FIG. 5 demonstrates the effect of the laser on the ion beam current with short and long pulses,

FIG. 6 demonstrates also the effect of the laser on the ion beam current with long pulses,

FIG. 7 demonstrates the effect of the laser on the ion source beam current when the hot filament ionizer is turned off, and no beam is normally observed.

FIG. 8 demonstrates that even a small laser power, even down to 49 mW, at the target position has a measurable effect on the ion beam current.

FIG. 9 illustrate a method according to the invention.

### DESCRIPTION OF THE INVENTION

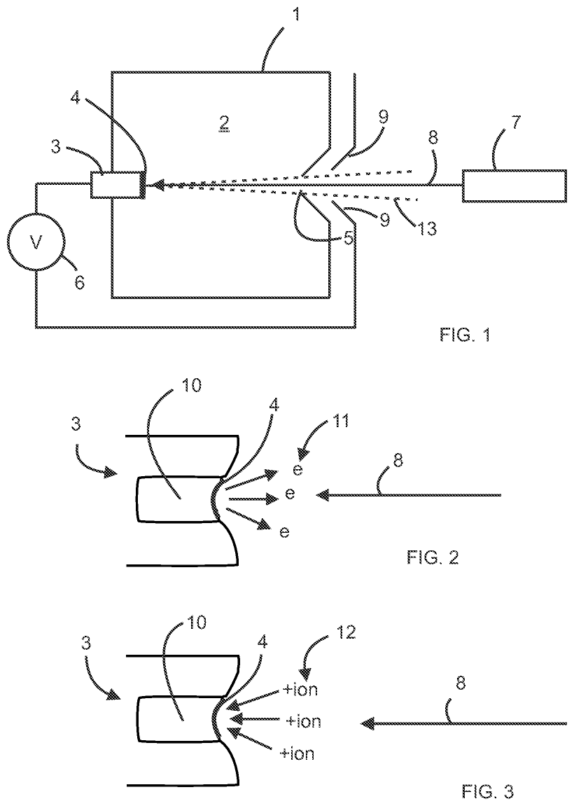

FIG. 1 illustrates a schematic example according to an inventive arrangement. An arrangement is made to produce for negative ions. It comprises a chamber 1 with a sputtering gas 2, a cathode 3, an alkali metal 4 in order to decrease a work function of the cathode, and an extraction channel 5. Further the arrangement comprises a voltage source 6 for providing an electric field in the chamber, which electric field's lowest voltage level is on the cathode 3, and a light source 7 to provide light 8 onto the cathode.

Sputtering gas can be any suitable gas which comprises for example oxygen or caesium. A cathode is any suitable material to produce negative ion. It can be for example Al2O3 or CsBr. Here the cathode material refers to an active material, which provides negative ions when the arrangement works. The active material can be in a solid, liquid or gaseous form.

An alkali metal 4 is used to decrease a work function on the surface of the cathode. The work function means energy which is needed to remove an electron outside from the cathode surface. An alkali metal such as ceasium has been found to be very convenient in this purpose.

The extraction channel 5 is a hole or pipe structure on the chamber 1 in order to provide route to negative ion beam outside form the chamber. An anode structure 9 is positioned near the extraction channel 5 for directing the negative ion beam through the extraction channel. As can be in FIG. 1, the cathode and the anode are connected to the voltage source 6. The potential of the electric field in the chamber (between the cathode and anode) can be 0.1-50 KV in an inventive arrangement.

The light source 7 provides light 8 onto the cathode. It is convenient that the light source is arranged to provide the light beam on the cathode through the extraction channel. It should be noted that FIG. 1 and also FIGS. 2-4 are schematic, and real arrangements looks very different. However, the schematic figures are very convenient to introduces the parts of the inventive arrangements in a clear way. The light source is a laser or a narrow-band diode, or another light source. The provided light is in a range of 100-1100 nm and it's power is at least 1 mW. Narrower ranges can also be utilized like 200-500 nm, or a narrow range around 450 nm.

FIGS. 2 and 3 show the cathode in a more detailed manner, where the active material 10 is situated in the center of the cathode. The cathode 3 in the chamber is arranged as response to said light 8 to induce photo-surface interaction, for example photoelectron emission from it, which results ionization of the sputtering gas 2. The photoelectrons are electrons which are revealed by the light from the surface of the cathode material/cathode. FIG. 2 shows the photoelectrons 11, and FIG. 3 shows positive ions 12 of the sputtering gas. The positive ions of the sputtering gas are arranged to bombard the cathode since the positive ions are directed to the cathode by the electric field. This is illustrated in FIG. 3. As response to said bombarding the cathode (cathode material) is arranged to provide (to sputter) negative ions from the cathode. The negative ion beam 13 radiates outside from the chamber 1 through the extraction channel 5 as illustrated in FIG. 1.

The produced negative ions depend on the material used in the cathode, the negative ion can, for example, be O⁻, Br⁻ anions from Al₂O₃ or CsBrrI cathodes respectively. The invention utilizes photo-surface interaction, for example photoelectric effect, and other effects on the surface of the cathode and/or the alkali metal coverage/saturation at the cathode surface. These effects can thus act as regulation for the ion beam production or boost/decrease the ion beam production. This happens through the work function, alkali metal coverage and with the modified/photo induced sputtering effect.

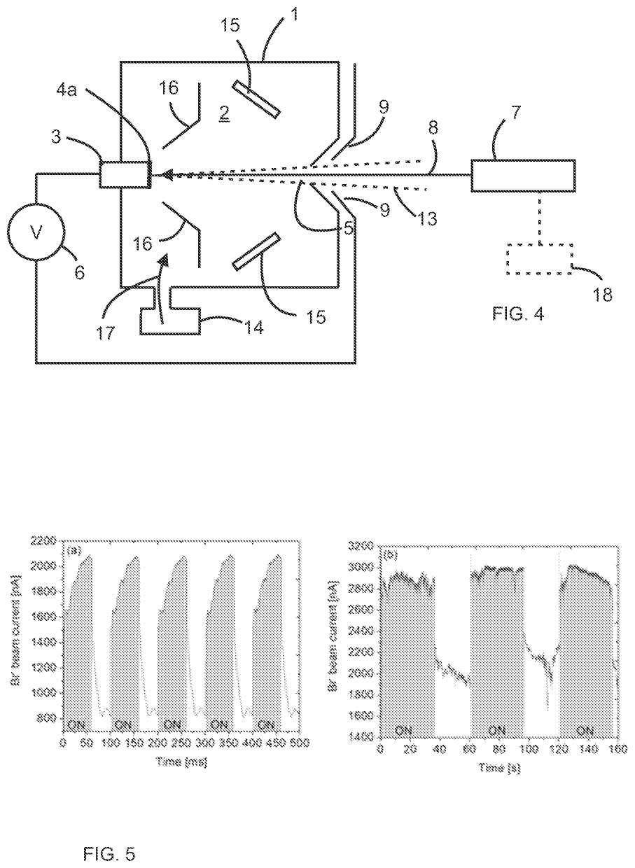

The alkali metal in the chamber 1 is within the sputtering gas or within the cathode. So, the cathode can be a compound material having, for example, caesium. FIG. 1 show an embodiment wherein caesium 4 is within the cathode. FIG. 4 shows another embodiment wherein the alkali metal, like caesium, is vaporized into the chamber 1 from an oven 14. So, this embodiment has a gas source to fed gas into the chamber for providing a portion of the sputtering gas. The oven is called by the alkali metal used like a caesium oven. In this description the caesium is used as an alkali metal, although another alkali metal can be used. The vaporized caesium, which is now in the sputtering gas 2 is ionized by at least one ionizer 15. The ionizer/s can be heated by a power source (not shown in the figures). The positive caesium ions are further directed towards the cathode by a focusing electrode 16 that is also called as immersion lens. Some of the positive caesium ions 4a condensate onto the surface of the cathode 3. The embodiment of FIG. 2 has the same effects caused by the light 8 as described above regarding the embodiment of FIG. 1.

The inventive arrangement may also have a controller 18 to control the light provided onto the cathode. The controller is illustrated in FIG. 4, but also the embodiment of FIG. 1 may have the controller. The controller can be used as feedforward controller or a feedback controller, or a combination of these types. It is noticeable that the invention can also work without any special controller. The controller can anyway be used to stabilize the negative ion production. The controller can adjust the light power, and also the duration of the light (light pulse periods), and decrease or increase the extracted ion beam. Further the controller makes it possible to select ion types, which are more interesting than other ion types. In other words, the negative ion beam can be controlled to contain a desired ion type/s mostly.

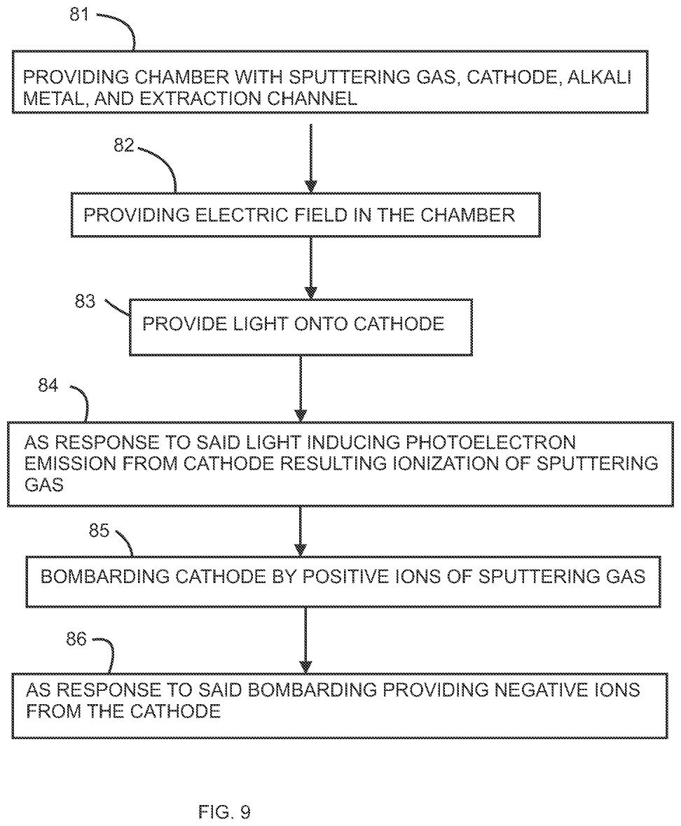

FIG. 9 illustrates an inventive method. An inventive method is for negative ion production. It comprises step of providing 81 a chamber with a sputtering gas, a cathode, an alkali metal in order to decrease a work function of the cathode, and an extraction channel; providing 82 an electric field in the chamber, which electric field's lowest voltage level is on the cathode; and providing 83 light onto the cathode. As response to said provided light, the method has also the step of inducing 84 photo-surface interaction from the cathode, which results ionization of the sputtering gas. Further the method comprises the steps of bombarding 85 the cathode by positive ions of the sputtering gas, the positive ions being directed to the cathode by the electric field; and providing 86 negative ions from the cathode as response to said bombarding.

Also, in the method the alkali metal in the chamber is provided within the sputtering gas or within the cathode, and the provided light is in a range of 100-1100 nm and it's power is at least 1 mW. Further, the potential of the electric field can be 0.1-50 kV.

Further in the method, the chamber can further be provided with at least one ionizer for ionizing the sputtering gas. At least one ionizer is powered for heating it. Further in the method, the chamber can be fed by a gas for providing a portion of the sputtering gas. The method may further comprise a step of controlling the light provided onto the cathode.

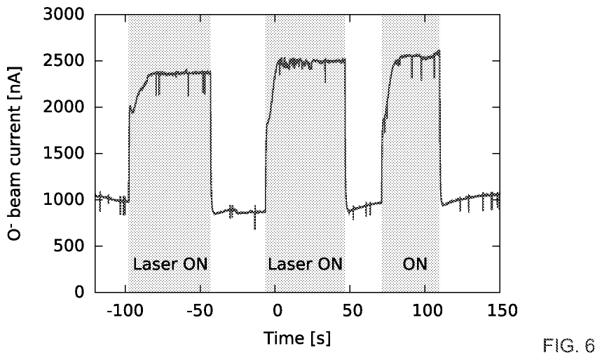

FIGS. 5-8 illustrate different experiments showing the effect of light on the cathode. FIG. 5 demonstrates the effect of the laser (445 nm) on the ion beam current with short and long pulses. FIG. 5 shows the effect on the Br− beam current for the 6 W (output) diode laser. So, CsBr or CsCl is the cathode material FIG. 6 shows the effect on the O− beam current for the 6 W (output) diode laser. The laser pulses are highlighted with gray background and the corresponding laser pulse powers are shown as curves. As can be noted the light beam has a significant effect on the produced ion beam.

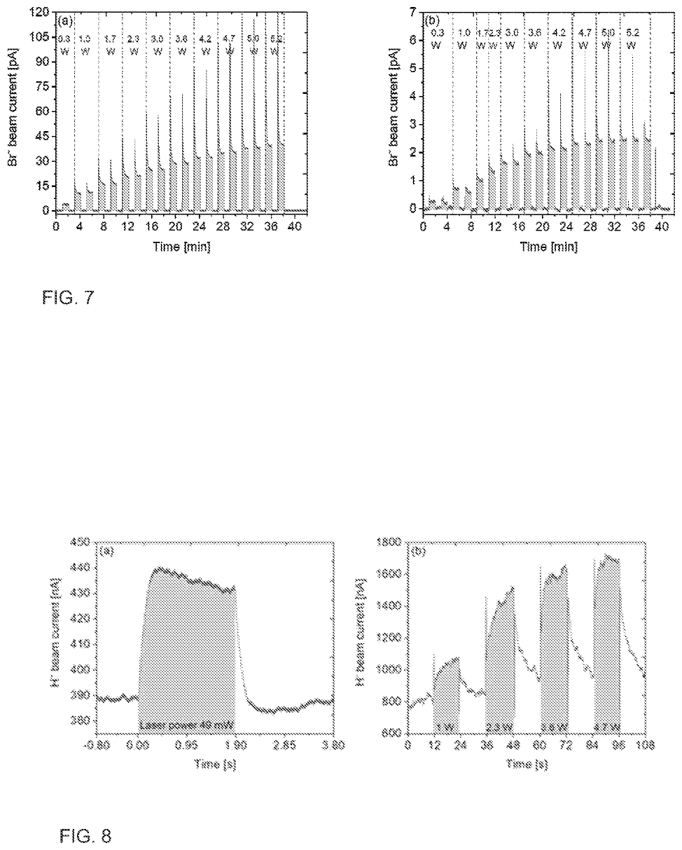

FIG. 7 demonstrates the effect of the laser on the ion source beam current when the hot filament ionizer is turned off, and no ion beam is normally observed. The data was measured with 5.5 A ionizer current (nominally not producing any beam) and (a) 160° C. Cs oven temperature, (b) without the Cs oven ON. So, FIG. 7 illustrates the effect of the laser to the Br− ion beam current, when the hot filament ionizer is turned to very small, 5.5 A value which normally doesn't produce any beam, and there is no alkali metal evaporation from the Cs oven. The laser pulses are highlighted with gray background and the corresponding laser pulse powers are indicated as curves. Target material (i.e. the cathode material) was CsBr. The effect of the light pulses is noticeable.

FIG. 8 demonstrates that even a small laser power, even down to 49 mW, at the target position has a measurable effect on the ion beam current. In other word, FIG. 8 shows a demonstration of low power versus higher power laser effect to the negative ion beam current. The effect on the H− beam current for the (a) Toptica DLC DL pro HP laser with 49 mW laser output power and (b) the effect of the LE-445-6000 diode laser output power on the H− beam current. The laser pulse length is 1.90 s in (a) and 12 s in (b), both having a 50% duty factor. Enhancement of the negative ion beam is: (a) 10-12% and (b) 100-113%. Measured values for the laser power at the source/target position are order of 1-10% compared to the given laser output power values.

So, the invention increases negative ion source ion beam current without the necessity of having a hot filament or a hot surface ionizer. However, also a hot surface ionizer may be used, and the disclosed solution will improve the stability, or modify the intensity, of the ion beam when applied to e.g. existing installations including the hot filament ion sources. The invention can be applied with a typical SNICS ion source (Source of Negative Ions by Caesium Sputtering).

The invention works without or with an ionizer, which is heated. As said above the sputtering gas can be any suitable gas, for example argon, hydrogen, helium, neon etc. The ionizing element of the sputtering gas can also be delivered into chamber outside, for example using a caesium oven and its connection to the chamber as described above. The inventive arrangement can be simpler and more cost-effective than known arrangements. The ionizer is not needed, and therefore there is no need the heat the ionizer (a heating filament on the ionizer). The negative ion beam can be produces completely without the hot filament. This may allow usage of very fast laser pulses, not just milliseconds or microseconds, but even femtoseconds laser pulses are available, to be used as pulsed ion beam production.

Photo-enhanced negative ion production may boost or stabilize practically any ion species produced by negative ion source. It may also decrease unwanted ion species while stabilizing or increasing the required ion beam intensity. For example, negative hydrogen beam can be enhanced with the laser in this type of ion sources.

As said the invention utilizes photo-surface interaction (for example photoelectric effect), and other effects on the cathode surface, which modifies the surface of the cathode and/or the alkali metal coverage/saturation at the cathode surface. These effects can thus act as regulation for the ion beam production or boost/decrease the ion beam production. This happens through the work function, alkali metal coverage and with the modified/photo induced sputtering effect.

The invention allows the lasers to be tuned such that the fine-tuning of the beam output current can be done faster than the conventional methods. In addition, the invention allows ultra-short pulses to be obtained from the ion source. The ultra-short pulses may be defined by the laser on-off period (and electron/ion transport times). Laser method can be faster than the voltage pulsing method which is currently used for beam pulsing techniques.

The invention also enables the finetuning and stabilization of the ion beam current in the existing high power ion sources, by controlling the laser power.

The invention can be used for any ion species capable forming negative ions, thus it can help to increase ion beam currents also for the “difficult-to-produce”-ion beams as well as hydrogen, for example. The present disclosure works with all negative ions. The invention does not require a so called resonance phenomenon.

If a hot surface ionizer is used the invention may be used to stabilize the ion beam, due to improved control. This is due to the fact that the light source, for example the laser, is, in contrast to the hot surface ionizer, fully externally controllable and faster in controlling the ion beam. The light is ‘instantly’ either on or off, the hot surface requires additional time for heat dissipation. Also, the intensity of the light source can be tuned in much faster speed than for example high voltages.

The invention can be installed to practically any type of negative ion source. The invention makes it possible to control and fine tune the ion source currents also for other alkali metal based negative ion sources and existing high power/high intensity H-ion sources.

So, the light booster/stabilizer according to the invention can be designed to be used in not only in the common SNICS type ion sources but many other type ion sources where surface conditions (work function) is lowered by alkali metal, for example caesium. Potentially much wider usages could be seen than just negative sputtering type ion sources. For example, H-ion sources using alkali metal and using lasers, or any suitable light source, for optimizing the alkali metal coverage of the ion source could be used.

The inventive solution presented solves or at least partially alleviates the problem to stabilize, increase or decrease negative ion source ion beam current without the necessity of increasing the temperature of the ionizer, or voltages within the existing ion sources. The light source and necessary optics can be attached to existing ion sources, in some cases without any other modifications to the existing components or ion source parameters.

The disclosed solution may use any alkali metals, not only caesium, thereby providing a potential for extending the choice of ionizing techniques. The disclosed solution enables operating typical surface ionisation ion sources without powering the hot ionizer, thus simplifying the ion source design and potentially reducing the power requirements of alkali sputtering ion sources.

The disclosed solution may be used in negative ion sources without the necessity to evaporate alkali metal vapour into the ionization chamber when the cathode (target) material is an alkali-compound. The invention allows facilitating the sputtering process with other elements, e.g. argon.

It is evident from the above that the invention is not limited to the embodiments described in this text but can be implemented in many other different embodiments within the scope of the independent claims.

1. A method for negative ion production, wherein the method comprises step of
providing a chamber with a sputtering gas, a cathode, an alkali metal in order to decrease a work function of the cathode, and an extraction channel,
providing an electric field in the chamber, which electric field's lowest voltage level is on the cathode,
providing controlled light onto the cathode
as response to said provided controlled light, inducing controlled photo-surface interaction from the cathode, providing photoelectron emission from the cathode, which results ionization of the sputtering gas,
bombarding the cathode by positive ions of the sputtering gas without using a hot surface in the chamber, the positive ions being directed to the cathode by the electric field,
providing desired negative ions from the cathode as response to said bombarding.

2. A method according to claim 1, wherein the alkali metal in the chamber is provided within the sputtering gas or within the cathode.

3. A method according to claim 1, wherein the provided light is in a range of 100-1100 nm and it's power is at least 1 mW.

4. A method according to claim 1, wherein potential of the electric field is 0.1-50 kV.

5. A method according to claim 1, wherein the chamber is further provided with at least one ionizer for ionizing the sputtering gas.

6. A method according to claim 1, wherein the chamber is fed by a gas for providing a portion of the sputtering gas.

7. A method according to claim 1, wherein it further comprises a step of controlling the light provided onto the cathode.

8. An arrangement to produce for negative ions, wherein it comprises
a chamber with a sputtering gas, a cathode, an alkali metal in order to decrease a work function of the cathode, and an extraction channel,
a voltage source for providing an electric field in the chamber, which electric field's lowest voltage level is on the cathode,
a light source to provide controlled light onto the cathode, in which chamber the cathode is arranged as response to said light to induce controlled photo-surface interaction from it providing photoelectron emission from the cathode, which results ionization of the sputtering gas,
positive ions of the sputtering gas being arranged to bombard the cathode without using a hot surface in the chamber, the positive ions being directed to the cathode by the electric field,
as response said bombarding the cathode being arranged to provide desired negative ions from the cathode.

9. An arrangement according to claim 8, wherein the alkali metal in the chamber is within the sputtering gas or within the cathode.

10. An arrangement according to claim 9, wherein the light source is a laser or a narrow-band diode.

11. An arrangement according to claim 10, wherein the light is in a range of 100-1100 nm and it's power is at least 1 mW.

12. An arrangement according to claim 8, wherein potential of the electric field is 0.1-50 kV.

13. An arrangement according to claim 8, wherein the chamber has at least one ionizer for ionizing the sputtering gas.

14. An arrangement according to claim 8, wherein the arrangement has a gas source to fed gas into the chamber for providing a portion of the sputtering gas.

15. An arrangement according to claim 8, wherein it has a controller to control the light provided onto the cathode.
